(19) United States
(12) Patent Application Publication
(10) Pub. No.: US 2025/0120241 A1
(43) Pub. Date: Apr. 10, 2025

(54) DISPLAY SUBSTRATE, TRANSFER ASSEMBLY, TRANSFER METHOD AND DISPLAY DEVICE

(71) Applicant: BOE TECHNOLOGY GROUP CO., LTD., Beijing (CN)

(72) Inventor: Haixu Li, Beijing (CN)

(73) Assignee: BOE TECHNOLOGY GROUP CO., LTD., Beijing (CN)

(21) Appl. No.: 18/836,078

(22) PCT Filed: May 16, 2023
(86) PCT No.: PCT/CN2023/094593

§ 371 Date: Aug. 6, 2024

(30) Foreign Application Priority Data
May 17, 2022 (CN) 202210540423.7

(51) Int. Cl. H10H 29/85; H10H 29/03; H10H 29/80; H10H 29/855

(52) U.S. Cl. CPC H10H 29/857; H10H 29/03; H10H 29/8552; H10H 29/942

(57) ABSTRACT

A display substrate, including a first substrate and a backplane arranged in a sequentially laminated manner, and a light-emitting layer, where the light-emitting layer includes a binding pads and a light-emitting elements arranged one-to-one corresponding to each other, where the binding pad is arranged on a side of the backplane away from the first substrate, and a pin of the light-emitting element is electrically connected to the binding pad, where the binding pad includes a first region and a second region, the orthographic projection of the first region on the backplane is covered by the orthographic projection of the light-emitting element on the backplane, and the orthographic projection of the second region on the backplane is arranged on the outer side of the orthographic projection of the light-emitting element on the backplane.

### CROSS-REFERENCE TO RELATED APPLICATION

The present disclosure claims a priority to the Chinese patent application No. 202210540423.7 filed in China on May 17, 2022, a disclosure of which is incorporated herein by reference in its entirety.

### TECHNICAL FIELD

The present disclosure relates to the field of display device technology, in particular to a display substrate, a transfer assembly and transfer method for light-emitting element, and a display device, and further to a display device.

### BACKGROUND

Currently, Micro LEDs or Mini LEDs having a smaller size can more easily achieve a high resolution, for example, smartphones or virtual reality screens of a 4K or even an 8K resolution can be obtained. In addition to the above advantages, Micro LEDs or Mini LEDs also have greater advantages in contrast, color gamut, and flexible display screens, all of which give Micro LEDs or Mini LEDs technology significant advantages compared to OLED technology.

In the laser mass dissociation process for panel products of Micro LEDs and Mini LEDs, the spot used is a Gaussian spot emitted by the laser, which needs to be used after DOE shaping. After shaping, the flat-top profile of the spot is generally about 80%, while the laser dissociation adhesive material can only utilize this 80% portion. Therefore, approximately another 20% of the light is irradiated on the outside of the light-emitting elements, that is, on the film layer structure of the backplane that is not covered by the light-emitting elements, which can severely affect the characteristics of the backplane and stability of the film layer.

### SUMMARY

In view of this, the embodiment of the disclosure provides a display substrate, a transfer assembly and a transfer method for light-emitting elements, and further provides a display device to solve the technical problem that the shaped spot will irradiate the backplane in the laser dissociation process in the prior art, affecting the stability of the backplane film layer.

To achieve the above purpose, a display substrate is provided according to one aspect of the embodiments of the disclosure.

The display substrate provided in the embodiment of the present disclosure includes a first substrate and a backplane arranged in a sequentially laminated manner, and a light-emitting element, where a binding pad correspondingly connected to the light-emitting element is arranged on a side of the backplane away from the first substrate, and a pin of the light-emitting element is electrically connected to the binding pad, where the binding pad includes a first region and a second region, the orthographic projection of the first region on the backplane is covered by the orthographic projection of the light-emitting element on the backplane, and the orthographic projection of the second region on the backplane is arranged on the outer side of the orthographic projection of the light-emitting element on the backplane.

In the display substrate provided by the embodiment of the present disclosure, the size of the binding pad is enlarged so that it extends to the outside of the light-emitting element so that it can be used in the manufacturing process of the display substrate to block the dissociation light emitting to the backplane, and reduce the influence of the light on the characteristics of the backplane and the stability of the film layer.

Furthermore, the distance between the edge of the binding pad and the light-emitting element in a first direction is 1/15-⅕ of the size of the light-emitting element in the first direction.

Furthermore, the distance between the edge of the binding pad and the light-emitting element in the first direction is ⅛ of the size of the light-emitting element in the first direction.

Furthermore, the second region is enclosed around the light-emitting element.

Furthermore, the binding pad includes a first pad and a second pad, where a trench between the first pad and the second pad is arranged on a side of the backplane away from the first substrate, and the first pad and/or the second pad extend into the trench, so that the first pad and the second pad have spacing in the direction perpendicular to the backplane.

Furthermore, the first pad extends to the bottom of the trench, the side wall of the trench close to the second pad is arranged perpendicular to the backplane, and the edge of the second pad close to the trench is flush with the side wall of the trench close to the second pad.

Furthermore, the display substrate further includes a passivation layer covering the backplane and the binding pad, and an opening that exposing part of the binding pad is formed by the passivation layer in the region corresponding to the pins of the light-emitting element.

Furthermore, a light-shielding layer is arranged on a side of the passivation layer away from the backplane, and the orthographic projection of the light-shielding layer on the backplane at least completely covers the orthographic projection of the second region on the backplane.

Furthermore, the light-shielding layer is doped with an ultraviolet absorbent.

In order to achieve the above purpose, according to the second aspect of the embodiment, a light-emitting element transfer assembly is further provided.

The light-emitting element transfer assembly according to the embodiment of the present disclosure includes:
a first substrate and a backplane are arranged in a sequentially laminated manner;
a binding pad arranged on a side of the backplane away from the first substrate, where the binding pad includes a first region and a second region;
a second substrate;
a light-emitting element attached on the second substrate through a dissociable-adhesive; where
the dissociable-adhesive is configured to dissociate after being irradiated by a target light, so that the light-emitting element detached from the second substrate falls into the binding pad, the orthographic projection of the first region on the backplane is covered by the orthographic projection of the light-emitting element on the backplane, and the orthographic projection of the second region on the backplane is arranged on the outer side of the orthographic projection of the light-emitting element on the backplane.

In order to achieve the above purpose, a light-emitting element transfer method is further provided according to the third aspect of the embodiment, and the light-emitting element transfer method is realized through the light-emitting element transfer assembly provided in the second aspect of the embodiment of the present disclosure.

The light-emitting element transfer method according to the embodiment of the present disclosure includes:
attaching the light-emitting element on the lower surface of the second substrate through the dissociable-adhesive;
forming the backplane on the first substrate, and manufacturing the binding pad at a preset position on the backplane;
moving the second substrate to the top of the backplane for alignment, so that the light-emitting elements on the second substrate are one-to-one aligned with the first region of the binding pad;
providing a target light on a side of the second substrate away from the dissociable-adhesive, where the target light passes through the first substrate to illuminate the dissociable-adhesive, causing the light-emitting element to detach from the second substrate and fall into the binding pad.

The light-emitting element transfer assembly and transfer method provided in the embodiment of the present disclosure can be used to block the light emitted to the backplane during the light-emitting element transfer process by enlarging the size of the binding pad so that it extends to the outside of the light-emitting element, and the influence of the light on the characteristics of the backplane and the stability of the film layer can be reduced.

The light-emitting element transfer assembly and transfer method provided in the embodiment of the present disclosure can be used to block the light emitted to the backplane during the light-emitting element transfer process by enlarging the size of the binding pad so that it extends to the outside of the light-emitting element, and the influence of the light on the characteristics of the backplane and the stability of the film layer can be reduced.

In order to achieve the above purpose, a display device is further provided according to the fourth aspect of the embodiment, and the display device includes the display substrate provided in the first aspect of the embodiment of the present disclosure.

In the display device provided in the embodiment of the present disclosure, the display substrate extends to the outside of the light-emitting element by enlarging the size of the binding pad, and in the manufacturing process of the display substrate, the binding pad blocks the light emitted to the backplane, and reduces the influence of the light on the characteristics of the backplane and the stability of the film layer.

### BRIEF DESCRIPTION OF THE DRAWINGS

FIG. 1 is a schematic diagram of the structure of a light-emitting element transfer assembly in the related technology;

FIG. 2 is a schematic diagram of the structure of a light-emitting element transfer assembly provided in the embodiment of the present disclosure;

FIG. 3 is a top diagram of the display substrate shown in FIG. 2;

FIG. 4 is a schematic diagram of the structure of the display substrate prepared by the transfer assembly in FIG. 2;

FIG. 5 is a schematic diagram of the structure of a display substrate provided in the embodiment of the present disclosure;

FIG. 6 is a top diagram of the display substrate shown in FIG. 5;

FIG. 7 is a schematic diagram of the structure of a light-emitting element transfer assembly provided in the embodiment of the present disclosure;

FIG. 8 is a schematic diagram of the structure of the display substrate prepared by the transfer assembly in FIG. 7;

FIG. 9 is a schematic diagram of the structure of a light-emitting element transfer assembly provided in the embodiment of the present disclosure;

FIG. 10 is a schematic diagram of the structure of the display substrate prepared by transfer assembly in FIG. 9:

FIG. 11 is a top diagram of the display substrate shown in FIG. 10; and

FIG. 12 is a schematic diagram of the structure of a display substrate provided in the embodiment of the present disclosure.

### In the Figure:

100 first substrate;
200 backplane; 201 trench;
300 Micro LED;
400 binding pad; 4-1 first region; 4-2 second region; 401 first pad; 4011 first section; 4012 second section; 4013 third section; 402 second pad;
500 dissociable-adhesive;
600 second substrate;
700 spacing;
800 passivation layer; 801 opening;
900 light-shielding layer.

### DETAILED DESCRIPTION

In order to enable a person skilled in the art to better understand the scheme, the following clearly and completely describes the technical solutions in the embodiments of this disclosure with reference to the accompanying drawings in the embodiments of this disclosure. Apparently, the described embodiments are some of the embodiments of this disclosure rather than all of the embodiments. All other embodiments obtained by a person of ordinary skill in the art based on the embodiments of this disclosure without creative efforts shall fall within the protection scope of this disclosure.

It should be noted that the terms “include” and “comprise” and any variations thereof in the description, claims and the above drawings of the present disclosure are intended to cover non-exclusive inclusions, for example, a system, product or equipment that including a series of units is not limited to those units that are clearly listed, but may include units that are not clearly listed or are inherent to those products or equipment.

In the present disclosure, orientation or positional relationships indicated by terms “upper”, “lower”, “inside”, “middle”, “outside” and the like are based on the orientation or positional relationships shown in the drawings. These terms are intended primarily to better describe the present disclosure and its embodiments, and are not intended to limit that the device, element or component indicated must have a particular orientation, or be constructed and operated in a particular orientation.

In addition, some of the above terms may be used to indicate other meanings in addition to a relationship of orientation or location, for example, the term “upper” may also be used to indicate a certain relationship of attachment or connection in some cases. For those of ordinary skill in the art, the specific meaning of these terms in the present disclosure may be understood on a specific case.

In addition, the terms “arrange”, “connect”, and “fix” should be understood in a broad sense. For example, the “connect” may be a fixed connection, a detachable connection, or a monolithic construction, a mechanical or electrical connection, a direct connection, an indirect connection through an intermediate medium, or an internal connection between two devices, components or constituents. Those of ordinary skills in the art may understand the specific meanings of the above-mentioned terms in the present disclosure according to situations.

It should be noted that, without conflict, the embodiments in the present disclosure and the features in the embodiments may be combined with each other.

The preparation process of Micro LED or Mini LED is to first thin film, miniaturize, and array the structure of the light-emitting diode to a size of only about 100-200 microns. The light-emitting diodes are then transferred to the circuit substrate in batches, and finally package it. Here, how to achieve batch transfer is the key difficulty in this process, which makes the mass transfer technology come into being. Mass transfer technology is a technology that installs light-emitting diodes formed on component substrates in batches onto circuit boards. Each light-emitting diode corresponds to a sub-pixel on the circuit substrate. Due to the size of the Micro LED or Mini LED is small, and millions of sub-pixels are required on the circuit substrate, how to transfer the light-emitting diode produced in batches to the corresponding position on the circuit substrate with high accuracy, is the technical problem that the technical personnel in the art urgently need to solve at present.

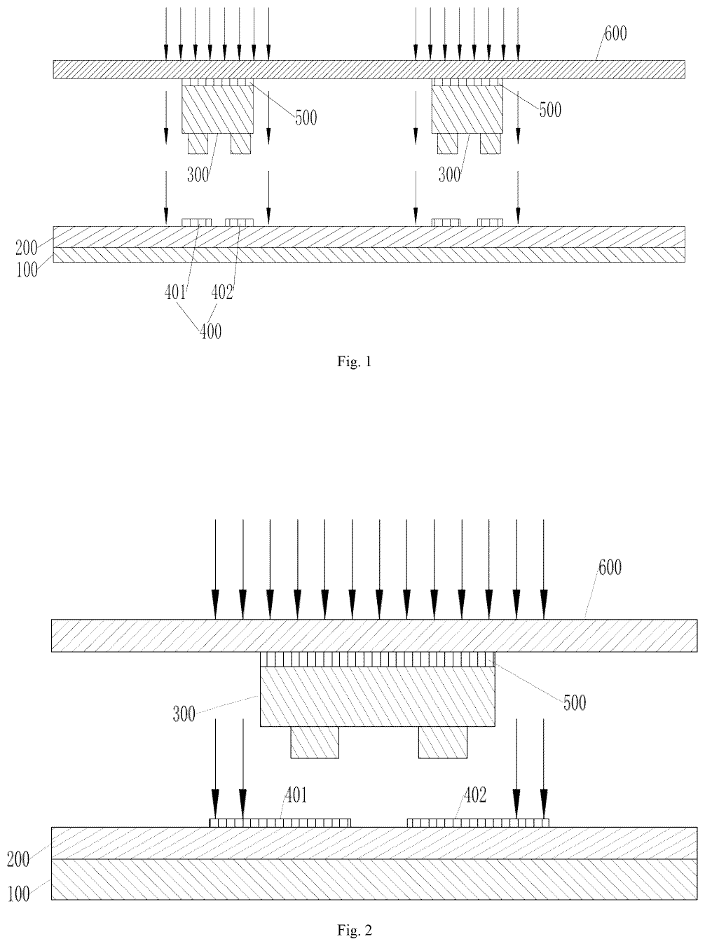

As shown in FIG. 1, a light-emitting element transfer assembly is provided, including a first substrate 100, a backplane 200, a second substrate 600 and a light-emitting element, where a binding pad 400 is arranged on the backplane 200 for realizing electrical connection with the pins of the light-emitting element, the light-emitting element is attached on a preset position of the second substrate 600 through a dissociable-adhesive 500, so that the pin of the light-emitting element is connected with the binding pad 400 on the backplane 200.

In the process of mass transfer of the light-emitting element, the dissociable-adhesive 500 is irradiated by laser light through the second substrate 600, so that the dissociable-adhesive 500 can be decomposed, and then the light-emitting element is detached from the second substrate 600 and transferred to the backplane 200. In the structure shown in FIG. 1, the shape of the dissociable-adhesive 500 is usually designed to cover or at least match the surface shape of the light-emitting element. In the laser mass dissociation process of Micro LED 300 and Mini LED panel products, the spot is the Gaussian spot emitted by the laser, and the beam needs to be used after DOE shaping, and the shaped beam is schematically represented by the arrow line in the figure. After shaping, the flat-top profile of the spot is generally about 80%, and the laser dissociation adhesive material can only utilize this 80% portion. Therefore, in order to achieve the maximum energy utilization efficiency, the shape of the flat-top part of the spot is shaped to coincide with the top surface of the light-emitting element. Then there will be another about 20% or so of the rising edge part of the light irradiated on the outside of the light-emitting element and will not be used to decompose the dissociable-adhesive 500. The part of the light will not be consumed, and the part of light will not be blocked by the light-emitting element on the outside of the light-emitting element. This part of the light will pass through the second substrate 600 and then irradiate on the film structure of the backplane 200 that the light-emitting element can not cover, which seriously affecting the characteristics of the backplane 200 and the stability of the film layer.

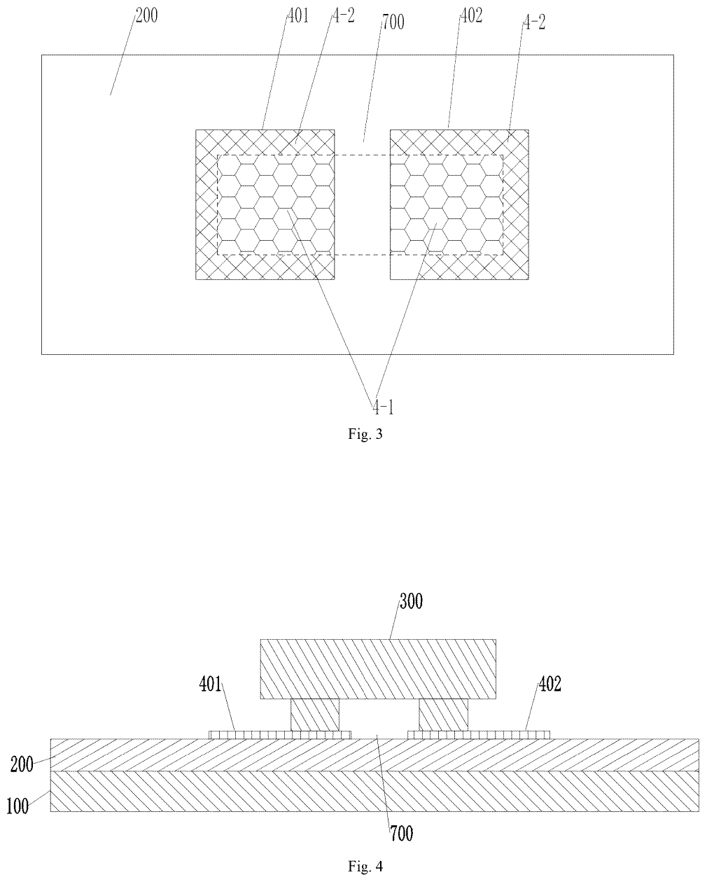

Based on this, the embodiment of the present disclosure has made certain improvements to the structure of the transfer assembly of the light-emitting element, as shown in FIG. 2 and FIG. 3. The transfer assembly of the light-emitting element of the embodiment of the present disclosure includes a transfer substrate and a display substrate. The dashed rectangular box in FIG. 3 represents the orthographic projection of the light-emitting element. The transfer substrate includes a second substrate 600 and a dissociable-adhesive 500, the display substrate includes a first substrate 100 and a backplane 200 arranged in a sequentially laminated manner, a binding pad 400 is arranged on the backplane 200, the binding pad 400 is arranged on a side of the backplane 200 away from the first substrate 100, and the binding pad 400 includes a first region 4-1 and a second region 4-2; the display substrate further includes a light-emitting element, and in the transfer assembly of the light-emitting element, the light-emitting element is fixed on the second substrate 600 through the dissociable-adhesive 500, specifically, where the dissociable-adhesive 500 is arranged in array on the same side of the second substrate 600, and one light-emitting element is attached with the second substrate 600 through the corresponding dissociable-adhesive 500. The dissociable-adhesive 500 is configured to dissociate after being irradiated by the target light, so that the light-emitting element is detached from the second substrate 600 and falls onto the binding pad 400, the orthographic projection of the first region 4-1 on the backplane 200 is covered by the orthographic projection of the light-emitting element on the backplane 200, and the orthographic projection of the second region 4-2 on the backplane 200 is located on the outer side of the orthographic projection of the light-emitting element on the backplane 200.

The binding pad 400 can be copper or other metal materials, and the binding pad 400 can be a single layer or a multilayer structure arranged in a sequentially laminated manner away from the direction of the first substrate 100, as long as it can conduct electricity and realize the blocking of the stray light of target light, and there is no special limitation.

It should be noted that the light-emitting elements in the above-mentioned embodiments of this disclosure include but are not limited to Micro LED 300. Mini LED, or other electronic light-emitting elements. For the convenience of illustration, the embodiments and accompanying drawings of this disclosure are illustrated with the light-emitting element as a Micro LED 300 as an example, and it will not be construed as a limitation for the scope of protection of the present disclosure.

The transfer method using the light-emitting element transfer assembly described above includes the following steps:

Step 1, attaching the light-emitting element on the lower surface of the second substrate 600 through a dissociable-adhesive 500.

The shape and size of the second substrate 600 can be specifically selected according to needs, for example, the shape of the second substrate 600 can be rectangular, and the size of the second substrate 600 can be 6 inch, 8 inch or 12 inch. The second substrate 600 is preferably a glass substrate, of course, in practical application, the second substrate 600 can also use other types of materials, which is not limited here, as long as the function of attaching a Micro LED 300 through the dissociable-adhesive 500 and light transmission can be realized.

In this step, a whole layer of dissociation adhesive layer can be formed on a side of the second substrate 600 at first, and then a whole layer of dissociation adhesive layer is patterned, to obtain the dissociable-adhesive 500 of array arrangement, and each dissociable-adhesive 500 is located at the position corresponding to the Micro LED 300. Specifically, a coating process can be used to form a dissociation adhesive layer on the second substrate 600, such as a spin coating process and a spraying process, and the dissociation adhesive layer covers the entire surface of the second substrate 600. Then, a composition process is adopted to pattern the dissociation adhesive layer to form a plurality of dissociable-adhesive 500 arranged in an array, and the composition process can include a photolithography process and an etching step, and the etching gas can be oxygen. Here, the photolithography process refers to the process of using photoresist, mask, exposure machine, etc. to form a pattern, including exposure, development and other processes. In the specific implementation, the corresponding composition process may be selected according to the structure formed in the present disclosure. Of course, other processes can also be used, such as an array arrangement of dissociable-adhesive 500 formed by a printing processes, which is not limited here.

It should be noted that in this embodiment of the disclosure, there is no specific limitation on the material of the dissociable-adhesive 500. As long as it has a certain viscosity, light within a certain wavelength range can be used for dissociation, so that the material of the Micro LED 300 attached to the dissociable-adhesive 500 that can be detached is applicable.

During the process of attaching the Micro LED 300 onto the dissociable-adhesive 500, the geometric center of the Micro LED 300 is controlled to be aligned with the geometric center of the dissociable-adhesive 500, that is, to ensure that the dissociable-adhesive 500 is located at the geometric center of the corresponding plane of the Micro LED 300 as much as possible, so that the force on the micro light-emitting diode 300 is more uniform in all directions and to avoid positional displacement.

Step 2, forming a backplane 200 on the first substrate 100, and manufacturing a binding pad 400 at a preset position on the backplane 200.

The shape and size of the first substrate 100 can be selected according to specific needs. For example, the shape of the first substrate 100 can be rectangular, and the size of the first substrate 100 can be 6 inches, 8 inches, or 12 inches. The first substrate 100 is preferably a glass substrate. However, in practical applications, other types of materials can also be used for the first substrate 100, and there is no limitation.

The backplane 200 formed on the first substrate 100 includes a plurality of pixel regions arranged in an array, and these pixel regions can correspond one-to-one with the binding pad 400. Each pixel region is provided with a binding pad 400 required for the connection of a miniature light-emitting diode 300, and the binding pad 400 is used for binding the Micro LED 300, and usually the binding pad 400 required for the connection of a Micro LED 300 includes a first pad 401 and a second pad 402, which are respectively connected with two pins of the Micro LED 300. The backplane 200 is also provided with a driving circuit for driving the miniature light-emitting diode 300. After the Micro LED 300 is correspondingly bound to the pixel region, the Micro LED 300 can be connected with the driving circuit by binding pad 400, and the drive circuit can realize the display function for the drive of the Micro LED 300.

A key point of the embodiment of the disclosure is that a set of binding pads 400 corresponding to each Micro LED 300 includes a first region 4-1 and a second region 4-2, and in the case that the micro-light-emitting diode 300 is assembled on a backplane 200, the orthotropic projection of the first region 4-1 on the backplane 200 is covered by the projection of the light-emitting element (e.g., the Micro LED 300) on the backplane 200, and the positive projection of the second region 4-2 on the backplane 200 is arranged on the outer side of the orthographic projection of the light-emitting element (e.g., the Micro LED 300) on the backplane 200.

Specifically, the formation of each film layer in the backplane 200, the setting of the driving circuit, and the manufacturing process of binding pads 400 may all adopt the process in the prior art, and the embodiment of the disclosure is not specifically limited.

Step 3, moving the second substrate 600 to the top of the backplane 200 for alignment, so that the light-emitting elements on the second substrate are one-to-one aligned with the first region of the binding pad. The purpose of this step is to make the Micro LED 300 on the second substrate 600 all be arranged directly above the corresponding binding pad 400, and after the dissociable-adhesive 500 is decomposed, the Micro LED 300 will fall onto the corresponding binding pad 400 under the action of gravity, and realize the electrical connection between the pins of the Micro LED 300 and the binding pad 400.

Step 4, providing a target light on a side of the second substrate 600 away from the dissociable-adhesive 500, and the target light is irradiated on the dissociable-adhesive 500 through the second substrate 600, so that the light-emitting element falls from the second substrate 600 onto the binding pad 400 to obtain a display substrate as shown in FIG. 4.

In this step, through the irradiation of the target light, the dissociable-adhesive 500 can be decomposed by the target light and lose its adhesion, so that the second substrate 600 and the Micro LED 300 attached to it are detached, so that each Micro LED 300 on the second substrate 600 can be transferred to the corresponding region on the backplane 200 at one time.

The embodiment of the disclosure also correspondingly protects the final product, i.e., a display substrate, obtained by the light-emitting element assembly and the transfer method of the above embodiment. As shown in FIG. 4, the display substrate includes a first substrate 100 and a backplane 200 arranged in a sequentially laminated manner, and a light-emitting element, where a binding pad 200 corresponding to the light-emitting element is arranged on a side of the backplane 200 away from the first substrate 100, and a pin of the light-emitting element is electrically connected to the binding pad 400, where the binding pad 400 includes a first region 4-1 and a second region 4-2, the orthographic projection of the first region 4-1 on the backplane 200 is covered by the orthographic projection of the light-emitting element on the backplane 200, and the orthographic projection of the second region 4-2 on the backplane 200 is arranged on the outer side of the orthographic projection of the light-emitting element on the backplane 200.

In the display substrate provided in the above embodiment, by enlarging the size of the binding pad 400 so that it extends to the outside of the light-emitting element, it can be used to block the dissociation light emitted to the backplane 200 in the manufacturing process of the display substrate, and reduce the influence of the light on the characteristics of the backplane 200 and the stability of the film layer.

In the transfer assembly used for manufacturing the display substrate, on the transfer substrate, the specific size of the dissociable-adhesive 500 corresponding to each light-emitting element in the direction perpendicular to the thickness of the second substrate 600 corresponds to the capability of the existing target light manufacturer, so long as the orthographic projection of the dissociable-adhesive 500 on the second substrate 600 can be completely arranged in the spot formed by the target light on the second substrate 600. Under normal circumstances, the shape and size of the dissociable-adhesive 500 is matched with the shape of the top surface of the light-emitting element, so that the light-emitting element can be fully attached with the second substrate 600. In order to make the target light evenly and collimatedly applied on the second substrate 600, and can adapt to the material of most of the dissociable-adhesive 500, the target light is preferably a laser, and specifically, the target light is an ultraviolet laser.

The target light of the embodiment of the present disclosure is preferably the light emitted by the laser, the beam emitted by the laser needs to be used after DOE shaping. The middle part of the spot after shaping has a good flat-top profile, the edge of the spot forms the rising edge part of the energy changed sharply, and the flat-top part of the spot is preferably shaped to be consistent with the shape and size of the top surface of the light-emitting element, so that the flat-top part of the spot is completely acting on the dissociable-adhesive 500 corresponding to the top surface of the light-emitting element, and the maximum energy utilization efficiency can be realized. The light from the rising edge will pass through the second substrate 600, forming a stray light that irradiates on the outside of the light-emitting element. The stray light will be blocked by the second region 4-2 of the binding pad 400, and the stray light blocked by the binding pad 400 will not irradiate on the backplane 200, thereby reducing the impact of stray light on the backplane 200. Assuming that the stray light is irradiated onto the backplane 200, the energy of the laser near the 355 nm wavelength is stronger than visible light. The characteristics of low-temperature polysilicon and oxides in the film layer of the backplane 200 will inevitably be affected, leading to characteristic drift and affecting the stability of the backplane 200. The second region 4-2 formed by the extension of the binding pad 400 can effectively solve the technical problems mentioned above. From another perspective, in the transfer assembly of the embodiment of the present disclosure and the structure of the final display substrate, the improved scheme adopted is to increase the area of the binding pad 400, that is, a second region 4-2 is formed, and only the size of the binding pad 400 needs to be adjusted in the manufacturing process, and no additional redundant process is added, and the production cost is reduced.

In the light-emitting element transfer assembly provided in the embodiment of the present disclosure and the final manufactured display substrate, the distance between the edge of the binding pad 400 and the light-emitting element, that is, the width of the second region 4-2, will be designed so that the stray light transmitted can be blocked as much as possible, that is, the coverage area of the second region 4-2 is as large as possible. However, based on product miniaturization and cost considerations, the second region 4-2 cannot be increased indefinitely, and its width is just consistent with the coverage width of stray light. However, considering the alignment tolerance existing in the process production, the width of the actual second region 4-2 is better to be the coverage width of the stray light in the corresponding region plus the alignment tolerance. For example, when the alignment tolerance is 6.2 μm, the width of the second region 4-2 actually produced is better to add 6.2 μm to the coverage width of the stray light in the corresponding region.

In some embodiments of the present disclosure, the width of the flat-top part of the shaped spot is usually 80%, and the width of the rising edge part is usually 20%, that is, 10% of the rising edge part is distributed on each side of the flat-top part. In order to achieve complete optical blocking of the rising edge part, the width of the second region 4-2 need correspond at least to the width of the rising edge part on a side. Because the flat-top part of the spot is consistent with the upper surface of the light-emitting element, it is only necessary to make the width of the second region 4-2 in the first direction reach at least ⅛ of the size of the light-emitting element in the first direction, and the width of the second region 4-2 in the first direction is the distance between the edge of the binding pad 400 and the light-emitting element in the first direction. However, considering the alignment tolerance existing in the process production, the width of the second region 4-2 of the actual production will be the coverage width of the stray light in the corresponding region plus the alignment tolerance. For example, when the alignment tolerance is 6.2 μm, the minimum width of the actual second region 42 will be ⅛ of the size of the light-emitting element in the first direction plus 6.2 pun. It should be noted that because the proportion of the flat-top part of the spot and the rising edge part after shaping will have a range of variation according to the actual situation, the distance between the edge of the binding pad 400 and the light-emitting element in the first direction is 1/15-⅕ of the size of the light-emitting element in the first direction. The purpose of limiting the first direction in the present embodiment is to limit the dimensional relationship between the second region 4-2 and the light-emitting element in the same direction. For example, when the orthographic shape of a light-emitting element is rectangular, the first direction can be the length or width of the rectangle, and when the orthographic shape of the light-emitting element is circular, the first direction can be either the diameter direction.

In the light-emitting element transfer assembly and the final display substrate provided in the embodiment of the present disclosure, preferably, the second region 4-2 encloses the light-emitting element in a closed manner, that is, the second region 4-2 forms a closed annular structure surrounding the light-emitting element. Since the rising edge part of the shaped spot is surrounded by the flat-top part, in the process of the transfer of the light-emitting element, the stray light of the rising edge part will also irradiate the region surrounding the light-emitting element, and the second region 4-2 can be arranged in this way to achieve obstruction and blocking of the stray light in the circumferential direction of the light-emitting element.

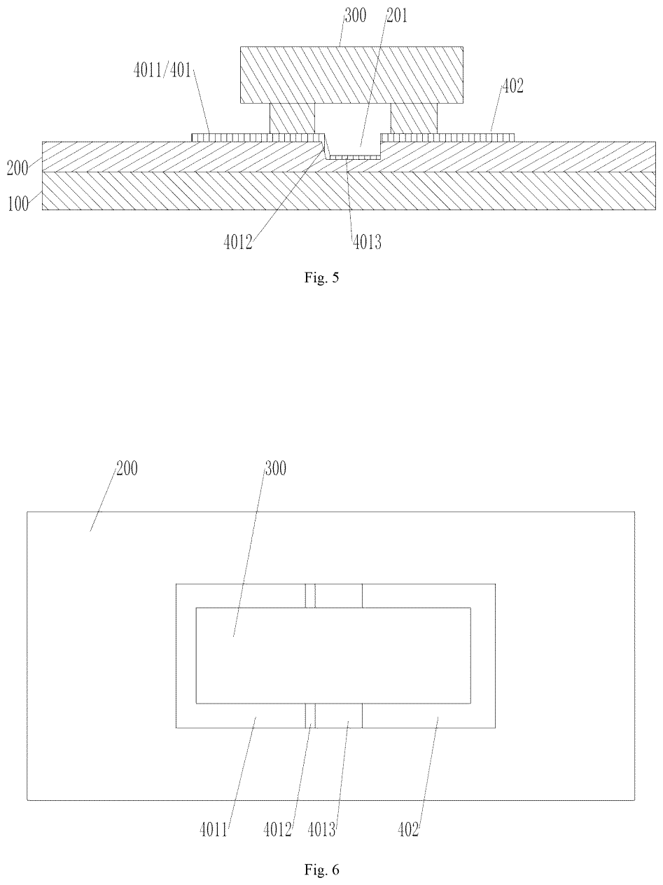

In the light-emitting element transfer assembly and the final manufactured display substrate, the light-emitting element is a light-emitting diode, such as a Micro LED 300 and a Mini LED. The light-emitting element usually includes two pins for connecting with the binding pad 400, and the binding pad 400 corresponding to each light-emitting element includes a first pad 401 and a second pad 402, which are respectively used for connecting with two pins of the Micro LED 300, and the first pad 401 and the second pad 402 cannot be directly connected or contacted. In this case, as shown in FIG. 3 and FIG. 4, when the first pad 401 and the second pad 402 are all on the surface of the backplane 200, there will be a spacing 700 between the first pad 401 and the second pad 402, so that the second region 4-2 of the binding pad 400 cannot complete the enclosed surrounding of the light-emitting element. The backplane 200 at a spacing 700 will still be exposed to stray light, which will also have a certain impact on the characteristics of the backplane 200. Based on this, as shown in FIGS. 5 and 6, a trench 201 is formed on the surface of the backplane 200 in the light-emitting element transfer assembly and the final display substrate of the embodiment of the disclosure. The trench 201 is arranged between the two pins of the light-emitting element, and the first pad 401 and/or the second pad 402 extend into the trench 201. With the help of the characteristic of a certain depth of the trench 201, the first pad 401 and the second pad 402 include a spacing in the direction perpendicular to the backplane 200, so that the physical partition is realized. In the orthographic projection formed on the backplane 200, the second region 4-2 formed by the first pad 401 and the second pad 402 together can be enclosed around the light-emitting element. For example, as shown in the figure, the side wall of the trench 201 away from the second pad 402 is obliquely arranged with respect to the surface of the backplane 200, and the sidewall of the trench 201 near the second pad 402 is arranged perpendicularly with respect to the surface of the backplane 200, so that the cross-section of the trench 201 forms a right-angled trapezoidal shape. The first pad 401 includes a first section 4011 arranged on the surface of the backplane 200. The first section 4011 extends along the inclined sidewall of trench 201 to form an inclined second section 4012 at the bottom of trench 201, and continues to fill the bottom of the trench to form a third section 4013. The edge of the second pad 402 is flush with the vertical sidewall of trench 201. At this moment, the first pad 401 and the second pad 402 can be separated by the vertical side wall of the trench 201, and in the orthographic projection formed on the backplane 200, the first pad 401 and the second pad 402 are just connected together, so that the requirement that the second region 4-2 surround the light-emitting element can be satisfied, and the circumferential direction is fully blocked from stray light. Of course, the shape of the trench 201 can also be selected as other forms; the second pad 402 can also be extended into the design form in the trench 201; the first pad 401 and the second pad 402 can be extended into the trench 201, for example, the first pad 401 on a side of the light-emitting element extends into the trench 201, and the second pad 402 on the other side of the light-emitting element extends into the trench 201.

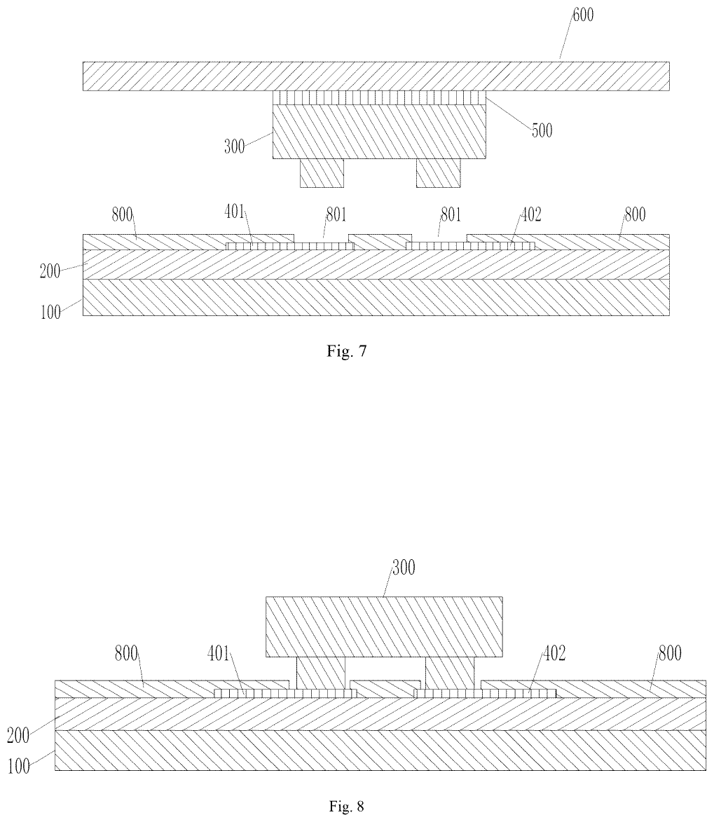

As shown in FIG. 7 and FIG. 8, the light-emitting element transfer assembly and the final manufacture display substrate further include a passivation layer 800 covering the backplane 200 and the binding pad 400 to protect the surface of the backplane 200. The passivation layer 800 forms an opening 801 that exposing the binding pad 400 in the region corresponding to the pin of light-emitting element. Each opening 801 penetrates through the passivation layer 800 along the thickness direction of the passivation layer 800, and exposes each binding pad 400 corresponding to the pins of the light-emitting element one-to-one, so that the pins of the light-emitting element are connected with the binding pad 400.

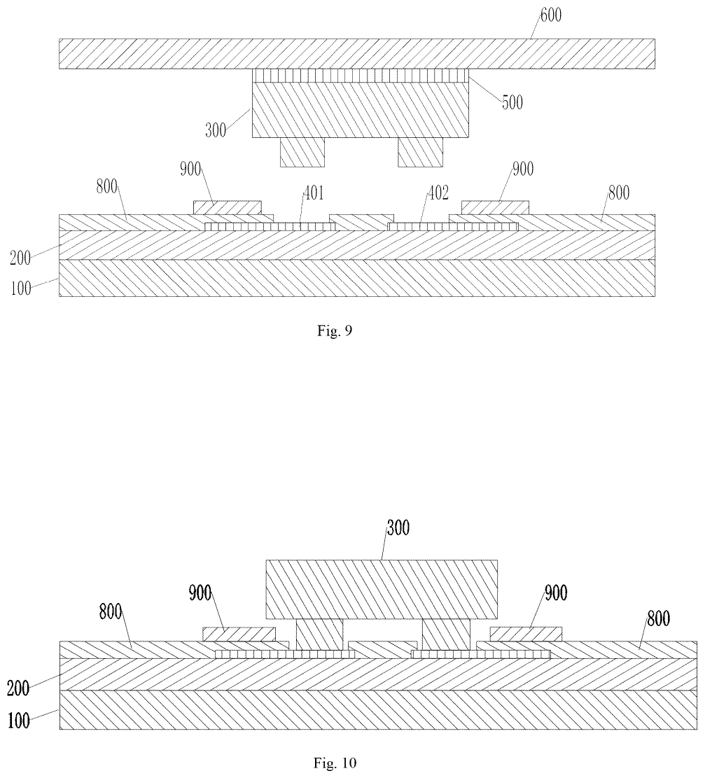

As shown in FIGS. 9 to 11, based on the above implementation, a light-shielding layer 900 is arranged on a side of the passivation layer 800 away from the backplane 200. The orthographic projection of the light-shielding layer 900 on the backplane 200 at least completely covers the orthographic projection of the second region 4-2 on the backplane 200. Due to the enlarged region of the binding pad 400 forming a second region 4-2, the visible light emitted by the light-emitting element diagonally downwards will reflect light diagonally upwards upon the second region 4-2, causing interference with the light output of the display substrate. The arrangement of the light-shielding layer 900 can be used to block the visible light reflected upwards in the second region 4-2 of the binding pad 400, avoiding interference with the normal light output display of the display substrate. It is preferable that the orthographic projection of the light-shielding layer 900 on the backplane 200 completely covers the orthographic projection of the second region 4-2 on the backplane 200, so as to block more of the reflected light from the second region 4-2. In addition, it can be considered to moderately increase the area of the light-shielding layer 900 to cover the slanted reflected light at the outer edge of the second region 4-2. The edge of the light-shielding layer 900 is ideally possible to passivate the edge of the opening 801 on the passivation layer 800, and according to the current process, there will be alignment tolerance and exposure accuracy, and the edge of the light-shielding layer 900 and the passivation layer 800 after manufacturing will be 1-3 μm apart.

Optionally, as shown in FIG. 11, the design corresponding to the second region 4-2 of the binding pad 400 allows the shape of the light-shielding layer 900 to be arranged around the light-emitting element. It should be noted that whether it is the second region 4-2 of the top pad or the true light layer, in the case of surrounding the light-emitting element, the width of the second region 4-2 or the light-shielding layer 900 on each side around the light-emitting element can be designed to be the same, and the width of the second region 4-2 or the light-shielding layer 900 on each side around the light-emitting element can also be designed to be different in the case of taking into account the offset between the center of the light-emitting element and the center of the spot, and the specific design can be carried out according to actual needs.

The light-shielding layer 900 in the above embodiment is preferably formed by the process of gluing-exposure-developing-curing the light-shielding material, and the light-shielding material is preferably a material that has excellent blocking effect on visible light, such as acrylate and polyimide doped with carbon black, and can also be a coating for other polymers. In order to further reduce the influence of transmitted ultraviolet light on the backplane 200 during the transfer of light-emitting elements, ultraviolet absorbent can be added to the light-shielding material to improve the absorption effect of ultraviolet light, and the optional ultraviolet absorbent include but are not limited to 2-(2′-hydroxy-3′,5′-diter-phenyl)-5-chloride benzotriazole, which can strongly absorb ultraviolet light with a wavelength of 270-380 mm and have good chemical stability.

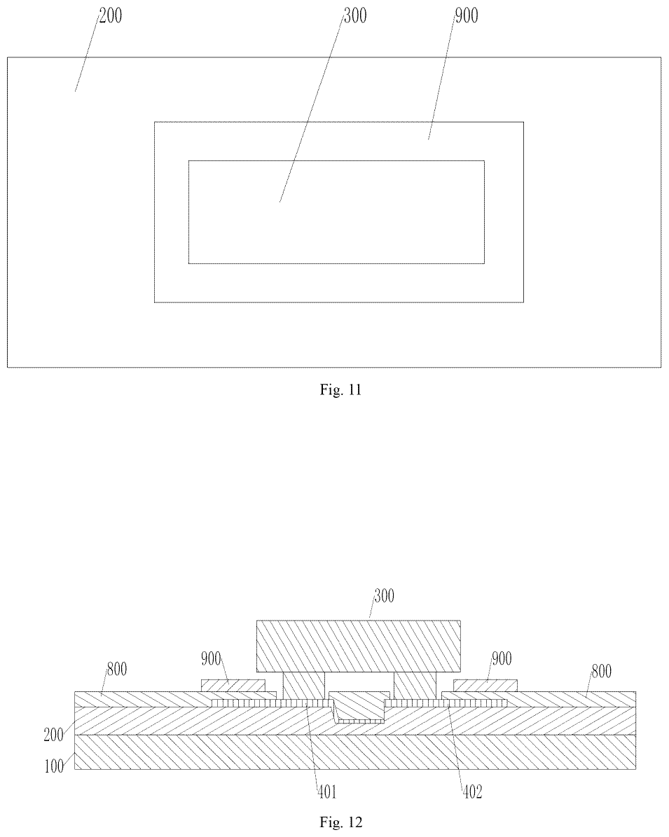

The embodiment of the substrate shown in FIG. 5-6 and the embodiment of the substrate shown in FIG. 10-11 can be combined with each other to obtain the display substrate represented in FIG. 12. A trench 201 is formed on the surface of the backplane 200, the trench 201 is arranged between the two pins of the light-emitting element, and the first pad 401 and/or the second pad 402 extends into the trench 201. With the help of the characteristic of a certain depth of the trench 201, the first pad 401 and the second pad 402 have a spacing in the direction perpendicular to the backplane 200, so that a physical partition is realized. In the orthographic projection formed on the backplane 200, the second region 4-2 formed by the first pad 401 and the second pad 402 together can be enclosed to surround the light-emitting element. For example, as shown in the figure, the side wall of the trench 201 far away from the second pad 402 is obliquely arranged with respect to the surface of the backplane 200, the side wall of the trench 201 away from the second pad 402 is vertically arranged with respect to the surface of the backplane 200, so that the cross-section of the trench 201 forms a right-angled trapezoidal shape. The first pad 401 includes a first section 4011 arranged on the surface of the backplane 200, the first section 4011 extends along the inclined side wall of the trench 201 to the bottom of the trench 201 to form an inclined second section 4012, and continues to cover the bottom of the trench to form a third section 4013 and the edge of the second pad 402 is flush with the vertical sidewall of the trench 201. At this moment, the first pad 401 and the second pad 402 can be separated by means of the vertical side wall of the trench 201, and in the orthographic projection formed on the backplane 200, the first pad 401 and the second pad 402 are just connected together, so that the requirements of the second region 4-2 surrounding the light-emitting element can be satisfied, and the stray light is comprehensively blocked in the circumferential direction. The display substrate also includes a passivation layer 800 covering the backplane 200 and the binding pad 400, protecting the surface of the backplane 200, where the passivation layer 800 forms an opening 801 that exposing part of the binding pad 400 in the region corresponding to the pins of the light-emitting element. Each opening 801 penetrates through the passivation layer 800 along the thickness direction of the passivation layer 800, and exposes each binding pad 400 corresponding to the pins of the light-emitting element one-to-one, so that the pins of the light-emitting element are connected with the binding pad 400. a light-shielding layer 900 is arranged on a side of the passivation layer 800 away from the backplane 200, and the orthographic projection of the light-shielding layer 900 on the backplane 200 at least completely covers the orthographic projection of the second region 4-2 on the backplane 200. Because the region of the binding pad 400 is enlarged to form the second region 4-2, the visible light emitted by the light-emitting element obliquely downward will form an obliquely upward reflected light after irradiating the second region 4-2, which causes interference to the light output of the display substrate. The arrangement of the light-shielding layer 900 can be used to block the visible light reflected upwards in the second region 4-2 of the binding pad 400, so as to avoid causing interference to the normal light output display of the display substrate. The orthographic projection of the light-shielding layer 900 on the backplane 200 should preferably completely cover the orthographic projection of the second region 4-2 on the backplane 200, so that the reflected light of the second region 4-2 can be more blocked.

The above is an exemplary description and explanation of the embodiment of the present disclosure regarding the transfer substrate and the transfer method for light-emitting elements, and the display substrate. The other components of the transfer substrate, the transfer method and the display substrate are known to those skilled in the art and are not described in detail herein, and those skilled in the art may understand and apply it with reference to the records of the prior art.

The embodiment of the disclosure also provides a display device using a display substrate provided in the above embodiments of the present disclosure, and the display device may, for example, be any product or part with display function, such as a liquid crystal panel, electronic paper, mobile phone, tablet computer, television, monitor, notebook computer, digital photo frame or navigator. The display device disclosed in the embodiment of the present disclosure adopts the display substrate provided by the above embodiment, so the display device also has all the above-mentioned technical effects, and will not be repeated herein. Other compositions, principles and preparation methods of the display device are known to those of ordinary people skilled in the art and will not be described in detail here.

The various embodiments in the present specification are described in a progressive manner, and each embodiment focuses on differences from other embodiments, and the same or similar parts between the various embodiments can be referred to each other.

The above is only a specific embodiment of the present disclosure, so that persons skilled in the art can understand or realize the present disclosure. Various modifications to the embodiments are obvious to persons skilled in the art. The general principles defined herein can be implemented in other embodiments without departing from the spirit or range of the present disclosure. Therefore, the present disclosure is not limited to the embodiments shown herein, but to conform to the widest range in line with the principles and novelty characteristics disclosed herein.

1. A display substrate, comprising a first substrate and a backplane arranged in a sequentially laminated manner, and a light-emitting element, wherein a binding pad correspondingly connected to the light-emitting element is arranged on a side of the backplane away from the first substrate, and a pin of the light-emitting element is electrically connected to the binding pad, wherein the binding pad comprises a first region and a second region, the orthographic projection of the first region on the backplane is covered by the orthographic projection of the light-emitting element on the backplane, and the orthographic projection of the second region on the backplane is arranged on the outer side of the orthographic projection of the light-emitting element on the backplane.

2. The display substrate according to claim 1, wherein the distance between the edge of the binding pad and the light-emitting element in a first direction is 1/15-⅕ of the size of the light-emitting element in the first direction, and the first direction is parallel to the backplane.

3. The display substrate according to claim 2, wherein the distance between the edge of the binding pad and the light-emitting element in the first direction is ⅛ of the size of the light-emitting element in the first direction.

4. The display substrate according to claim 1, wherein the second region is enclosed around the light-emitting element.

5. The display substrate according to claim 4, wherein the binding pad comprises a first pad and a second pad, wherein a trench between the first pad and the second pad is arranged on a side of the backplane away from the first substrate, and the first pad and/or the second pad extend into the trench, so that the first pad and the second pad have spacing in the direction perpendicular to the backplane.

6. The display substrate according to claim 5, wherein the first pad extends to the bottom of the trench, the side wall of the trench close to the second pad is arranged perpendicular to the backplane, and the edge of the second pad close to the trench is flush with the side wall of the trench close to the second pad.

7. The display substrate according to claim 1, wherein the display substrate further comprises a passivation layer covering the backplane and the binding pad, and an opening that exposing part of the binding pad is formed by the passivation layer in the region corresponding to the pins of the light-emitting element.

8. The display substrate according to claim 7, wherein a light-shielding layer is arranged on a side of the passivation layer away from the backplane, and the orthographic projection of the light-shielding layer on the backplane at least completely covers the orthographic projection of the second region on the backplane.

9. The display substrate according to claim 8, wherein the light-shielding layer is doped with an ultraviolet absorbent.

10. A light-emitting element transfer assembly, comprising:
a first substrate and a backplane arranged in a laminated manner;
a binding pad arranged on a side of the backplane away from the first substrate, wherein the binding pad comprises a first region and a second region;
a second substrate; and
a light-emitting element attached on the second substrate through a dissociable-adhesive; wherein
the dissociable-adhesive is configured to dissociate after being irradiated by a target light, so that the light-emitting element detached from the second substrate falls into the binding pad, the orthographic projection of the first region on the backplane is covered by the orthographic projection of the light-emitting element on the backplane, and the orthographic projection of the second region on the backplane is arranged on the outer side of the orthographic projection of the light-emitting element on the backplane.

11. A light-emitting element transfer method, realized by adopting the light-emitting element transfer assembly according to claim 10, wherein the light-emitting element transfer method comprises:
attaching the light-emitting element on the lower surface of the second substrate through the dissociable-adhesive;
forming the backplane on the first substrate, and manufacturing the binding pad at a preset position on the backplane;
moving the second substrate to the top of the backplane for alignment, so that the light-emitting elements on the second substrate are one-to-one aligned with the first region of the binding pad; and
providing a target light on a side of the second substrate away from the dissociable-adhesive, wherein the target light passes through the first substrate to illuminate the dissociable-adhesive, causing the light-emitting element to detach from the second substrate and fall into the binding pad.

12. A display device, comprising the display substrate according to claim 1.
